(19) United States
(12) Patent Application Publication
(10) Pub. No.: US 2026/0082748 A1
(43) Pub. Date: Mar. 19, 2026

(54) ASSEMBLING SUBSTRATE, DISPLAY DEVICE, AND METHOD OF MANUFACTURING DISPLAY DEVICE USING THE SAME

(71) Applicant: LG DISPLAY CO., LTD., SEOUL (KR)

(72) Inventors: MinSeok Kim, Seoul (KR); RokHee Lee, Seoul (KR); MoonBae Gee, Paju-si (KR); HyeongSeok Kim, Paju-si (KR)

(21) Appl. No.: 19/095,476

(22) Filed: Mar. 31, 2025

(30) Foreign Application Priority Data
Sep. 19, 2024 (KR) 10-2024-0126582

(51) Int. Cl. H10H 29/49; H10H 29/01; H10H 29/37

(52) U.S. Cl. CPC H10H 29/49; H10H 29/012; H10H 29/0364; H10H 29/37

(57) ABSTRACT

An assembling substrate which serves to assemble a plurality of light-emitting elements. The assembling substrate includes an assembly substrate, a plurality of first assembling electrodes disposed on the assembly substrate, a plurality of second assembling electrodes disposed on the assembly substrate and configured to face the plurality of first assembling electrodes at predetermined intervals, and an organic layer disposed on the assembly substrate and including a plurality of opening portions, wherein some of the plurality of first assembling electrodes include a plurality of first holes disposed to overlap the plurality of opening portions, wherein some of the plurality of second assembling electrodes include a plurality of second holes disposed to overlap the plurality of opening portions, and, wherein the plurality of first holes and the plurality of second holes are disposed to overlap the opening portions of some of the plurality of opening portions.

### CROSS-REFERENCE TO RELATED APPLICATIONS

This application claims the priority of Korean Patent Application No. 10-2024-0126582 filed on Sep. 19, 2024, in the Korean Intellectual Property Office, the disclosure of which is incorporated herein by reference in its entirety.

### TECHNICAL FIELD

The present specification relates to a display device and a method of manufacturing the same, and more particularly, to a display device, which uses a light-emitting diode (LED), and a method of manufacturing the same.

### BACKGROUND

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### SUMMARY

An object to be achieved by the present specification is to provide a display device capable of being assembled simultaneously, and a method of manufacturing the same.

Another object to be achieved by the present specification is to provide a display device capable of improving production efficiency by reducing the number of assembling processes, and a method of manufacturing the same.

Still another object to be achieved by the present specification is to provide a display device capable of reducing manufacturing costs, during self-assembly, by selectively assembling light-emitting elements, which can have the same size and emit light beams with different colors, even though the light-emitting elements are uniformly mixed, and a method of manufacturing the same.

Objects of the present disclosure are not limited to the above-mentioned objects, and other objects, which are not mentioned above, can be clearly understood by those skilled in the art from the following descriptions.

According to an aspect of the present disclosure, there is provided an assembling substrate which serves to assemble a plurality of light-emitting elements. The assembling substrate includes an assembly substrate, a plurality of first assembling electrodes disposed on the assembly substrate, a plurality of second assembling electrodes disposed on the assembly substrate and configured to face the plurality of first assembling electrodes at predetermined intervals, and an organic layer disposed on the assembly substrate and including a plurality of opening portions, wherein some of the plurality of first assembling electrodes include a plurality of first holes disposed to overlap the plurality of opening portions, wherein some of the plurality of second assembling electrodes include a plurality of second holes disposed to overlap the plurality of opening portions, and, wherein the plurality of first holes and the plurality of second holes are disposed to overlap the opening portions of some of the plurality of opening portions.

According to an aspect of the present disclosure, there is provided a method of manufacturing a display device. The method of manufacturing the display device includes self-assembling a plurality of light-emitting elements on an assembling substrate including a plurality of assembling electrodes, transferring the plurality of light-emitting elements self-assembled on the assembling substrate to a donor, and transferring the plurality of light-emitting elements on the donor to a display panel, wherein the plurality of light-emitting elements include a plurality of first light-emitting elements, a plurality of second light-emitting elements, and a plurality of third light-emitting elements, and wherein the self-assembling the plurality of light-emitting elements includes, assembling the plurality of first light-emitting elements on the assembling substrate by applying a first voltage to the plurality of assembling electrodes, and assembling the plurality of second light-emitting elements and the plurality of third light-emitting elements on the assembling substrate by applying a second voltage to the plurality of assembling electrodes.

According to an aspect of the present disclosure, there is provided a device. The device includes a substrate on which a plurality of subpixels is defined, a plurality of transistors respectively disposed on the plurality of subpixels on the substrate, and a plurality of light-emitting elements disposed on the plurality of subpixels and including a plurality of semiconductor layers and a plurality of electrodes, wherein the plurality of light-emitting elements include a plurality of first light-emitting elements, a plurality of second light-emitting elements, and a plurality of third light-emitting elements, wherein the plurality of light-emitting elements each includes the plurality of semiconductor layers and the plurality of electrodes, and wherein permittivity of the plurality of semiconductor layers of the plurality of second light-emitting elements and permittivity of the plurality of semiconductor layers of the plurality of third light-emitting elements are different from permittivity of the plurality of semiconductor layers of the plurality of first light-emitting elements.

Other detailed matters of the example implementations are included in the detailed description and the drawings.

According to the present specification, it is possible to optimize the process by simplifying the manufacturing process.

According to the present specification, it is possible to provide exclusivity to the light-emitting element in accordance with dielectric properties of the light-emitting element during self-assembly.

According to the present specification, the light-emitting elements, which emit light beams with various colors, can be selectively assembled on a single tray during self-assembly, which can reduce the number of manufacturing processes and the manufacturing costs.

According to the present specification, the light-emitting elements having the same size can be selectively assembled during self-assembly, which can reduce the number of manufacturing processes and the manufacturing costs.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a top plan view of an assembling substrate according to an implementation of the present specification;

FIG. 2 is an enlarged top plan view of an assembling area of an assembling substrate of a display device according to the implementation of the present specification;

FIG. 3 is an enlarged top plan view of a unit area of the assembling substrate of the display device according to the implementation of the present specification;

FIGS. 4A to 4C are cross-sectional views of opening portions of the assembling substrate of the display device according to the implementation of the present specification;

FIGS. 5A to 5I are process diagrams for explaining a method of manufacturing the display device according to the implementation of the present specification;

FIG. 6 is a schematic configuration view of the display device according to the implementation of the present specification; and

FIG. 7 is a cross-sectional view of the display device according to the implementation of the present specification.

### DETAILED DESCRIPTION

Advantages and characteristics of the present disclosure and a method of achieving the advantages and characteristics will be clear by referring to example implementations described below in detail together with the accompanying drawings. However, the present disclosure is not limited to the example implementations disclosed herein but will be implemented in various forms. The example implementations are provided by way of example only so that those skilled in the art can fully understand the disclosures of the present disclosure and the scope of the present disclosure.

The shapes, sizes, ratios, angles, numbers, and the like illustrated in the accompanying drawings for describing the example implementations of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various implementations of the present disclosure can be partially or entirely adhered to or combined with each other and can be interlocked and operated in technically various ways, and the implementations can be carried out independently of or in association with each other.

Hereinafter, a method of manufacturing a display device and a wafer according to example implementations of the present disclosure will be described in detail with reference to accompanying drawings.

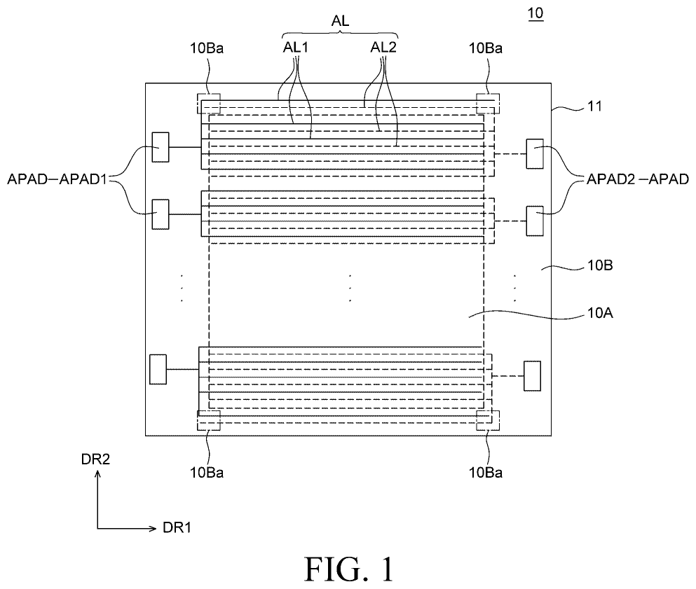

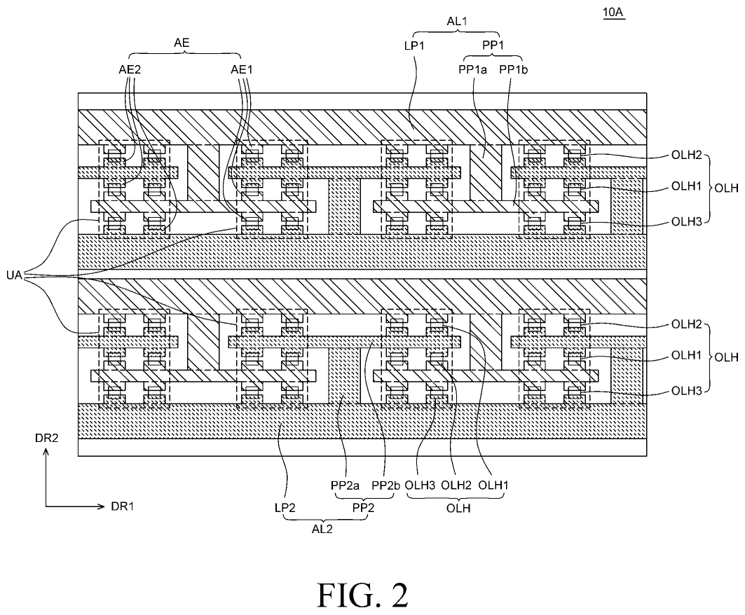

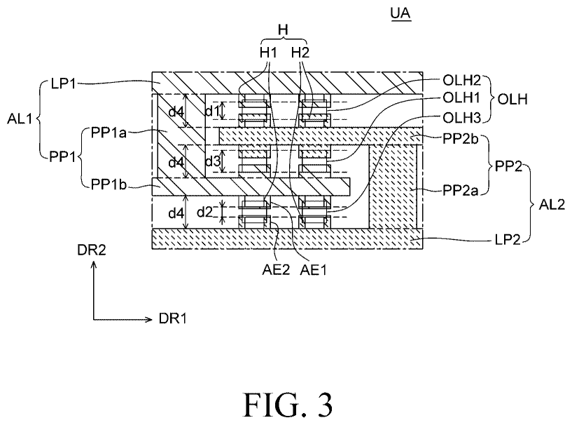

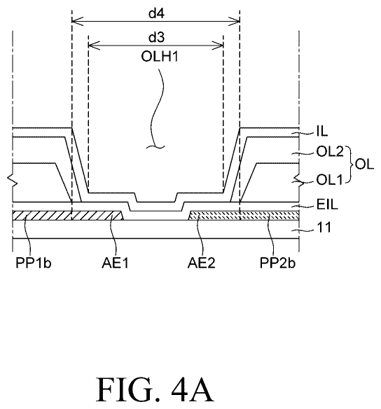

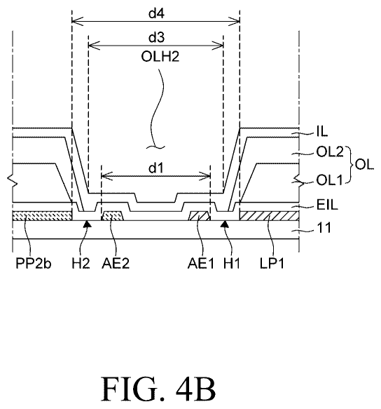

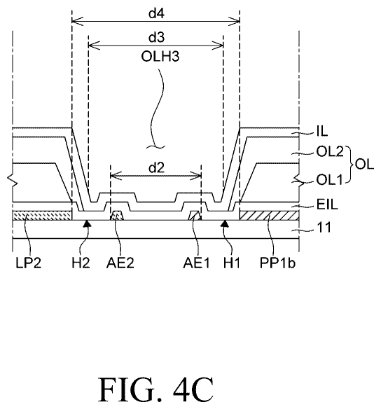

FIG. 1 is a top plan view of an assembling substrate according to an implementation of the present specification. FIG. 2 is an enlarged top plan view of an assembling area of an assembling substrate of a display device according to the implementation of the present specification. FIG. 3 is an enlarged top plan view of a unit area of the assembling substrate of the display device according to the implementation of the present specification. FIGS. 4A to 4C are cross-sectional views of opening portions of the assembling substrate of the display device according to the implementation of the present specification. FIG. 4A is a cross-sectional view of a first opening portion OLH1. FIG. 4B is a cross-sectional view of a second opening portion OLH2. FIG. 4C is a cross-sectional view of a third opening portion OLH3.

With reference to FIGS. 1 and 2 together, an assembling substrate 10 includes an assembling area 10A and an outer peripheral area 10B. The assembling area 10A is an area in which a plurality of light-emitting elements are self-assembled. A plurality of assembling lines AL and a plurality of assembling electrodes AE are disposed in the assembling area 10A to self-assemble the light-emitting elements. The outer peripheral area 10B is the remaining area excluding the assembling area 10A. A plurality of assembling pads, a plurality of alignment keys, and the like may be disposed in the outer peripheral area 10B.

With reference to FIGS. 1 to 4C, the assembling substrate 10 includes an assembly substrate 11, the plurality of assembling lines AL, the plurality of assembling electrodes AE, a plurality of assembling pads, an organic layer OL, an electrode insulation layer EIL, and an assembling insulation layer IL.

First, with reference to FIGS. 2 to 4C, the plurality of assembling lines AL and the plurality of assembling electrodes AE are disposed on the assembly substrate 11 in the assembling area 10A.

The plurality of assembling lines AL includes a plurality of first assembling lines AL1 and a plurality of second assembling lines AL2. The plurality of first assembling lines AL1 and the plurality of second assembling lines AL2 may be disposed to be spaced apart from one another at predetermined intervals. The plurality of first assembling lines AL1 and the plurality of second assembling lines AL2 may be alternately disposed. Different voltages may be applied to the plurality of first assembling lines AL1 and the plurality of second assembling lines AL2, such that an electric field may be formed between the plurality of first assembling lines AL1 and the plurality of second assembling lines AL2. Further, the plurality of light-emitting elements may be self-assembled between the plurality of first assembling lines AL1 and the plurality of second assembling lines AL2 by using the electric field formed between the plurality of first assembling lines AL1 and the plurality of second assembling lines AL2.

The plurality of first assembling lines AL1 each includes a first line portion LP1 and a plurality of first protruding portions PP 1. The first line portion LP1 is a portion extending straight in a first direction DR1 in the assembling area 10A. The first line portion LP1 may extend from the assembling area 10A to the outer peripheral area 10B and be electrically connected to the plurality of assembling pads in the outer peripheral area 10B.

The plurality of first protruding portions PP1 are connected to one first line portion LP1. The plurality of first protruding portions PP1 may extend from one side surface of the first line portion LP1 toward the adjacent second assembling line AL2. The plurality of first protruding portions PP1 may be disposed to self-assemble a plurality of first light-emitting elements, a plurality of second light-emitting elements, and a plurality of third light-emitting elements between one first assembling line AL1 and one second assembling line AL2 that are adjacent to each other. The plurality of first protruding portions PP1 may be disposed to be staggered from a plurality of second protruding portions PP2 of the second assembling line AL2 to be described below and form a plurality of electric fields for self-assembling the light-emitting elements so that the light-emitting elements correspond to a plurality of first subpixels, a plurality of second subpixels, and a plurality of third subpixels. Therefore, the plurality of first protruding portions PP1 are disposed in an area between the first assembling line AL1 and the second assembling line AL2, such that the first light-emitting element, the second light-emitting element, and the third light-emitting element may be self-assembled at intervals between the plurality of subpixels.

The plurality of first protruding portions PP1 may be connected to one first line portion LP1 to self-assemble all the first light-emitting element, the second light-emitting element, and the third light-emitting element between one first assembling line AL1 and one second assembling line AL2 that are adjacent to each other. Therefore, the plurality of first light-emitting elements, the plurality of second light-emitting elements, and the plurality of third light-emitting elements are self-assembled by using the same assembling line AL, such that design areas of the plurality of assembling lines AL may be ensured. In addition, a width of the assembling line AL may be ensured during the process in which the assembling line AL is formed to correspond to an interval between the subpixels. A deterioration in assembling rate may be suppressed by suppressing an increase in resistance.

The plurality of first protruding portions PP1 each include a first portion PP1a and a second portion PP1b. The first portion PP1a is a portion extending from the first line portion LP1 in a second direction DR2. The first portion PP1a may be a connection member configured to transmit a voltage to the second portion PP1b. One end of the first portion PP1a may be connected to the first line portion LP1, and the other end of the first portion PP1a may be connected to the second portion PP1b.

The second portion PP1b is a portion connected to the other end of the first portion PP1a and extending in the first direction DR1. The second portion PP1b may extend in the first direction DR1 and be disposed to be staggered from the second protruding portion PP2 of the second assembling line AL2. The second portion PP1b may be disposed in an area between a second line portion LP2 and a fourth portion PP2b of the second protruding portion PP2 of the second assembling line AL2. The second portion PP1b may be disposed adjacent to the second line portion LP2 and the fourth portion PP2b of the second protruding portion PP2 and form the electric field for self-assembling the plurality of first light-emitting elements, the plurality of second light-emitting elements, and the plurality of third light-emitting elements.

The plurality of second assembling lines AL2 each include the second line portion LP2 and the plurality of second protruding portions PP2. The second line portion LP2 is a portion extending straight in the first direction DR1 in the assembling area 10A. The second line portion LP2 and the first line portion LP1 may be disposed alternately in the second direction DR2. The second line portion LP2 may extend from the assembling area 10A to the outer peripheral area 10B and be electrically connected to the plurality of assembling pads in the outer peripheral area 10B.

The plurality of second protruding portions PP2 are connected to the second line portion LP2. The plurality of second protruding portions PP2 may extend in the second direction DR2 from the other side surface of the second line portion LP2. The plurality of second protruding portions PP2 each include a third portion PP2a and the fourth portion PP2b. The third portion PP2a is a portion extending from the second line portion LP2 in the second direction DR2. The third portion PP2a may be a connection member configured to transmit a voltage to the fourth portion PP2b. One end of the third portion PP2a may be connected to the second line portion LP2, and the other end of the third portion PP2a may be connected to the fourth portion PP2b. The third portion PP2a may be disposed to be staggered from the first portion PP1a of the adjacent first assembling line AL1. Therefore, the third portion PP2a and the first portion are disposed in a staggered manner, such that the fourth portion PP2b connected to the third portion PP2a and the second portion PP1b connected to the first portion PP1a may be disposed in a staggered manner.

The fourth portion PP2b is a portion connected to the other end of the third portion PP2a and extending in the first direction DR1. The fourth portion PP2b may extend in the first direction DR1 and be disposed to be staggered from the second portion PP1b of the first protruding portion PP1 of the first assembling line AL1. The fourth portion PP2b may be disposed in an area between the first line portion LP1 and the second portion PP1b of the first protruding portion PP1 of the first assembling line AL1. The fourth portion PP2b of the second assembling line AL2 and the second portion PP1b of the first assembling line AL1 may face each other in the second direction DR2. Therefore, the fourth portion PP2b of the second assembling line AL2, together with the second portion PP1b and the first line portion LP1 of the first assembling line AL1, may form the electric field for self-assembling the plurality of first light-emitting elements, the plurality of second light-emitting elements, and the plurality of third light-emitting elements.

The plurality of assembling electrodes AE includes a plurality of first assembling electrodes AE1 and a plurality of second assembling electrodes AE2. The plurality of first assembling electrodes AE1 may be connected to the plurality of first assembling lines AL1, and the plurality of second assembling electrodes AE2 may be connected to the plurality of second assembling lines AL2. The pair of first and second assembling electrodes AE1 and AE2 may be disposed adjacent to each other and form the electric field for self-assembling the light-emitting element. In the plurality of subpixels, the pair of first and second assembling electrodes AE1 and AE2 may be disposed to correspond to the exact position to which the light-emitting element is transferred.

Some of the plurality of first assembling electrodes AE1 may be disposed to protrude in the second direction DR2 from one side surface of the first line portion LP1. Some of the remaining first assembling electrodes AE1 may be disposed to protrude in the second direction DR2 from two opposite side surfaces of the second portion PP1b of the first protruding portion PP1. For example, four first assembling electrodes AE1 may be connected to two opposite side surfaces of one second portion PP1b.

Some of the plurality of second assembling electrodes AE2 may be disposed to protrude in the second direction DR2 from the other side surface of the second line portion LP2. Some of the second assembling electrodes AE2 connected to the second line portion LP2 may face the first assembling electrode AE1 protruding from the second portion PP1b of the adjacent first assembling line AL1. Some of the plurality of second assembling electrodes AE2 may protrude in the second direction DR2 from two opposite side surfaces of the fourth portion PP2b of the second protruding portion PP2. Further, among the second assembling electrodes AE2, the second assembling electrode AE2 protruding from one side surface of the fourth portion PP2b may face the first assembling electrode AE1 protruding from the other side surface of the second portion PP1b of the adjacent first assembling line AL1. The second assembling electrode AE2 protruding from the other side surface of the fourth portion PP2b may face the first assembling electrode AE1 protruding from the first line portion LP1 of the adjacent first assembling line AL1.

Further, any one of the first light-emitting element, the second light-emitting element, and the third light-emitting element may be self-assembled with an interval and arrangement corresponding to the plurality of subpixels between the first assembling electrode AE1 and the second assembling electrode AE2 that face each other. For example, the first light-emitting element may be self-assembled between the first assembling electrode AE1 of the first line portion LP1 and the second assembling electrode AE2 of the fourth portion PP2b that face each other, the second light-emitting element may be self-assembled between the first assembling electrode AE1 of the second portion PP1b and the second assembling electrode AE2 of the fourth portion PP2b that face each other, and the third light-emitting element may be self-assembled between the first assembling electrode AE1 of the second portion PP1b and the second assembling electrode AE2 of the second line portion LP2 that face each other.

Therefore, the plurality of first protruding portions PP1 and the plurality of second protruding portions PP2 are disposed in a staggered manner between one first assembling line AL1 and the second assembling line AL2 that are adjacent to each other, such that the first light-emitting element of the first subpixel, the second light-emitting element of the second subpixel, and the third light-emitting element of the third subpixel may be self-assembled at once.

Meanwhile, some of the plurality of assembling electrodes AE may include a plurality of holes H.

For example, some of the plurality of first assembling electrodes AE1 may include a plurality of first holes H1 disposed to overlap a plurality of opening portions OLH, and some of the plurality of second assembling electrodes AE1 may include a plurality of second holes H2 disposed to overlap the plurality of opening portions OLH.

With reference to FIG. 3, the plurality of first holes H1 and the plurality of second holes H2 may be disposed to overlap the opening portions OLH of some of the plurality of opening portions OLH. For example, the plurality of first holes H1 and the plurality of second holes H2 may be disposed to overlap the plurality of second opening portions OLH2 and the plurality of third opening portions OLH3 among the plurality of opening portions OLH.

Therefore, an area in which the plurality of first opening portions OLH1 overlap the plurality of assembling electrodes AE may be larger than an area in which the plurality of second opening portions OLH2 and the plurality of third opening portions OLH3 overlap the plurality of assembling electrodes AE.

The plurality of first holes H1 and the plurality of second holes H2 may be disposed between the first line portion LP1 and the fourth portion PP2b that are adjacent to each other, and the plurality of first holes H1 and the plurality of second holes H2 may be disposed between the second line portion LP2 and the second portion PP1b that are adjacent to each other. Meanwhile, the plurality of first holes H1 and the plurality of second holes H2 may not be disposed between the fourth portion PP2b and the second portion PP1b that are adjacent to each other.

For example, in the plurality of second opening portions OLH2, the first hole H1 may be disposed adjacent to the first line portion LP1. Therefore, in case that a planar shape of the first hole H1 is a quadrangular shape, one surface of the first hole H1 may be disposed on the same plane as one surface of the first line portion LP1, and the remaining three surfaces of the first hole H1 may be surrounded by the first assembling electrode AE1. However, the present specification is not limited thereto. The first hole H1 may be spaced apart from the first line portion LP1, and all the surfaces of the first hole H1 may be surrounded by the first assembling electrode AE1. In addition, in the plurality of second opening portions OLH2, the second hole H2 may be disposed adjacent to the fourth portion PP2b. Therefore, in case that a planar shape of the second hole H2 is a quadrangular shape, one surface of the second hole H2 may be disposed on the same plane as one surface of the fourth portion PP2b, and the remaining three surfaces of the second hole H2 may be surrounded by the second assembling electrode AE2. However, the present specification is not limited thereto. The second hole H2 may be spaced apart from the fourth portion PP2b, and all the surfaces of the second hole H2 may be surrounded by the first assembling electrode AE1.

In the plurality of third opening portions OLH3, the first hole H1 may be disposed adjacent to the second portion PP1b. Therefore, in case that a planar shape of the first hole H1 is a quadrangular shape, one surface of the first hole H1 may be disposed on the same plane as one surface of the second portion PP1b, and the remaining three surfaces of the first hole H1 may be surrounded by the first assembling electrode AEL. In addition, in the plurality of third opening portions OLH3, the second hole H2 may be disposed adjacent to the second line portion LP2. Therefore, in case that a planar shape of the second hole H2 is a quadrangular shape, one surface of the second hole H2 may be disposed on the same plane as one surface of the second line portion LP2, and the remaining three surfaces of the second hole H2 may be surrounded by the second assembling electrode AE2.

Meanwhile, the plurality of holes H may have different sizes. For example, as illustrated in FIG. 3, the sizes of the plurality of first holes H1 and the plurality of second holes H2, which overlap the plurality of third opening portions OLH3, may be different from the sizes of the plurality of first holes H1 and the plurality of second holes H2 that overlap the plurality of second opening portions OLH2. Meanwhile, the sizes of the first holes H1 and second holes H2, which overlap the same opening portions OLH2 and OLH3, may be equal to each other.

For example, with reference to FIGS. 4B and 4C together, the sizes of the plurality of first holes H1 and the plurality of second holes H2, which overlap the plurality of third opening portions OLH3, may be larger than the sizes of the plurality of first holes H1 and the plurality of second holes H2 that overlap the plurality of second opening portions OLH2.

Therefore, the area in which the plurality of second opening portions OLH2 overlap the plurality of assembling electrodes AE may be larger than the area in which the plurality of third opening portions OLH3 overlap the plurality of assembling electrodes AE.

Meanwhile, an interval d2 between the first holes H1 and second holes H2 adjacent to each other in each of the plurality of third opening portions OLH3 may be different from an interval d1 between the first holes H1 and second holes H2 adjacent to each other in each of the plurality of second opening portions OLH2. For example, the interval d2 between the plurality of first holes H1 and the plurality of second holes H2 in the plurality of third opening portions OLH3 may be smaller than the interval d1 between the plurality of first holes H1 and the plurality of second holes H2 in the second opening portion OLH2.

With reference to FIG. 1 together, the plurality of assembling pads are disposed on the assembling substrate 10 in the outer peripheral area 10B. The plurality of assembling pads includes a plurality of first assembling pads APAD1 and a plurality of second assembling pads APAD2. The plurality of first assembling lines AL1 and the plurality of first assembling electrodes AE1 may be connected to the plurality of first assembling pads APAD1 and receive voltages, and the plurality of second assembling lines AL2 and the plurality of second assembling electrodes AE2 may be connected to the plurality of second assembling pads APAD2 and receive voltages. The first assembling line AL1 of some of the plurality of first assembling lines AL1 may be connected to one first assembling pad APAD1, and the second assembling line AL2 of some of the plurality of second assembling lines AL2 may be connected to one second assembling pad APAD2.

With reference to FIGS. 4A to 4C, the electrode insulation layer EIL is disposed on the plurality of assembling lines AL and the plurality of assembling electrodes AE. The electrode insulation layer EIL may protect the plurality of assembling lines AL and the plurality of assembling electrodes AE from a fluid WT, thereby suppressing a defect such as corrosion of the plurality of assembling lines AL and the plurality of assembling electrodes AE. For example, the electrode insulation layer EIL may be made of oxide or nitride. For example, the electrode insulation layer EIL may be configured as a single layer or multilayer made of silicon oxide (SiOx) or silicon nitride (SiNx). However, the present specification is not limited thereto.

Next, the organic layer OL including the plurality of opening portions OLH is disposed on the electrode insulation layer EIL.

The organic layer OL includes a first organic layer OL1 and a second organic layer OL2. The first organic layer OL1 is disposed on the plurality of assembling lines AL, and the second organic layer OL2 is disposed on the first organic layer OL1. A thickness of the organic layer OL, which may be formed by one process, is limited. If the thickness of the organic layer OL is at a predetermined level or lower, the light-emitting element, which is self-assembled in the opening portion OLH of the organic layer OL, may not be properly seated in the opening portion OLH. On the contrary, in case that the thickness of the organic layer OL is excessively large, it may be difficult to attach the light-emitting element, which is self-assembled inside the opening portion OLH of the organic layer OL, to a donor 20. Therefore, the thickness of the organic layer OL may be adjusted by forming the organic layer OL as a plurality of layers. The organic layer OL may at least have a thickness smaller than a height of the light-emitting element. FIGS. 3 to 4C illustrates that the organic layer OL includes the first organic layer OL1 and the second organic layer OL2. However, the organic layer OL may be formed as a single layer or further include an additional organic layer OL in addition to the first organic layer OL1 and the second organic layer OL2. However, the present specification is not limited thereto.

The organic layer OL includes the plurality of opening portions OLH. The plurality of opening portions OLH, which are formed by opening a part of the organic layer OL, may be areas in which the plurality of light-emitting elements are self-assembled. The plurality of opening portions OLH may be disposed to overlap an area between the first assembling electrode AE1 and the second assembling electrode AE2.

The plurality of opening portions OLH include the plurality of first opening portions OLH1, the plurality of second opening portions OLH2, and the plurality of third opening portions OLH3.

With reference to FIG. 3, the pair of first opening portions OLH1, the pair of second opening portions OLH2, and the pair of third opening portions OLH3 may define unit areas UA. The unit area UA may be an area corresponding to one pixel. The unit areas UA may each be formed at a position corresponding to each of the plurality of pixels of the display device. The unit areas UA may be disposed to respectively correspond to the pixels in a one-to-one manner. The light-emitting element self-assembled in each of the unit areas UA may be transferred to each of the plurality of pixels.

For example, the plurality of first opening portions OLH1, the plurality of second opening portions OLH2, and the plurality of third opening portions OLH3 may be arranged to respectively correspond to the plurality of first subpixels, the plurality of second subpixels, and the plurality of third subpixels. Therefore, the light-emitting elements self-assembled in the plurality of opening portions OLH may be transferred to the plurality of subpixels in an intact manner.

Meanwhile, with reference to FIG. 3, the second opening portion OLH2, the first opening portion OLH1, and the third opening portion OLH3 may be sequentially disposed in one unit area UA. For example, the second opening portion OLH2, the first opening portion OLH1, and the third opening portion OLH3 may be sequentially disposed in the second direction DR2 between the first and second assembling lines AL1 and AL2 adjacent to each other.

Meanwhile, a width d3 of each of the plurality of opening portions OLH in the second direction DR2 may be smaller than an interval d4 between the first line portion LP1 and the fourth portion PP2b adjacent to each other, the interval d4 between the second line portion LP2 and the second portion PP1b adjacent to each other, and the interval d4 between the second portion PP1b and the third portion PP2a adjacent to each other.

Therefore, with reference to FIG. 4A, the organic layer OL may overlap a part of each of the plurality of first assembling electrodes AE1 and a part of each of the plurality of second assembling electrodes AE2.

Meanwhile, with reference to FIGS. 4B and 4C, the organic layer OL may cover a part of each of the plurality of first holes H1 and a part of each of the plurality of second holes H2. FIGS. 4B and 4C illustrate that the first organic layer OL1, between the first organic layer OL1 and the second organic layer OL2, covers a part of each of the plurality of first holes H1 and a part of each of the plurality of second holes H2. However, the present specification is not limited thereto. The second organic layer OL2 may also cover apart of each of the plurality of first holes H1 and a part of each of the plurality of second holes H2.

Meanwhile, a first light-emitting element 120, a second light-emitting element 130, and a third light-emitting element 140 may have the same planar shape. Therefore, the first opening portion OLH1, the plurality of second opening portions OLH2, and the plurality of third opening portions OLH3 may have the same planar shape. For example, the first opening portion OLH1, the plurality of second opening portions OLH2, and the plurality of third opening portions OLH3 may be identical in the width d3 to one another.

However, the present specification is not limited thereto. In case that the first light-emitting element 120, the second light-emitting element 130, and the third light-emitting element 140 have different planar shapes, the first opening portion OLH1, the plurality of second opening portions OLH2, and the plurality of third opening portions OLH3 may have different planar shapes.

The assembling insulation layer IL is disposed on the organic layer OL. The assembling insulation layer IL may protect the plurality of assembling lines AL, the plurality of assembling electrodes AE, and the organic layer OL from the fluid WT, thereby suppressing a defect such as corrosion of the plurality of assembling lines AL.

With reference to FIG. 1, the outer peripheral area 10B includes one or more first alignment areas 10Ba. For example, the plurality of first alignment areas 10Ba may be formed adjacent to four corners of the assembling area 10A.

In the first alignment area 10Ba, the assembling line AL and the assembling electrode AE may be further disposed on the assembling substrate 10.

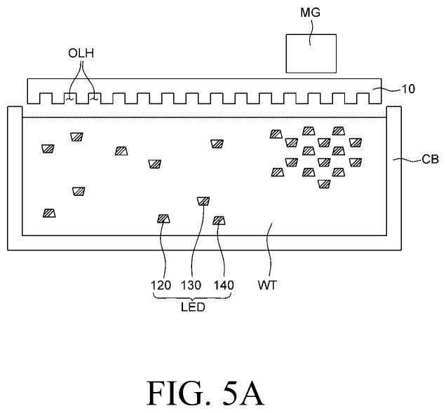

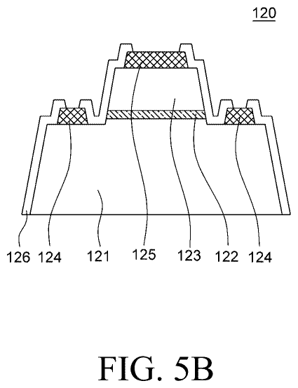

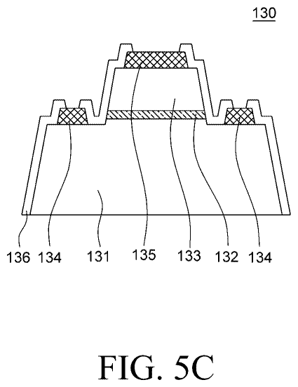

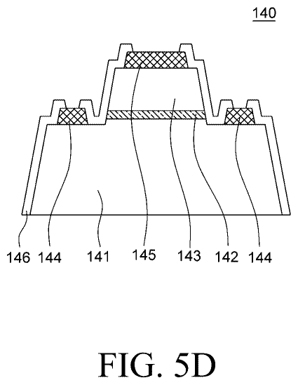

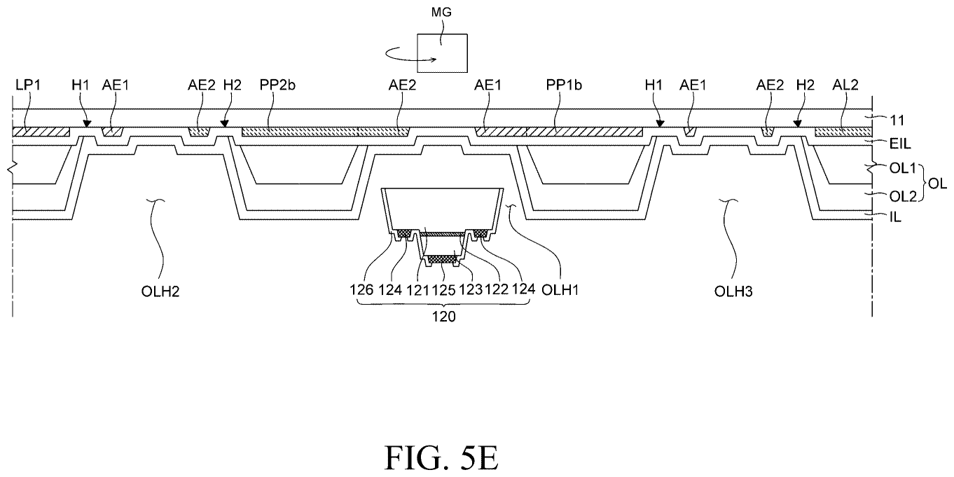

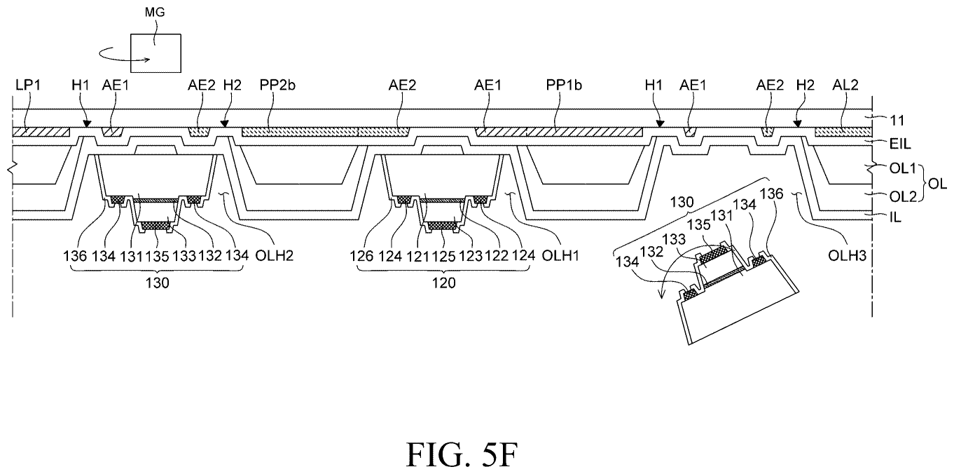

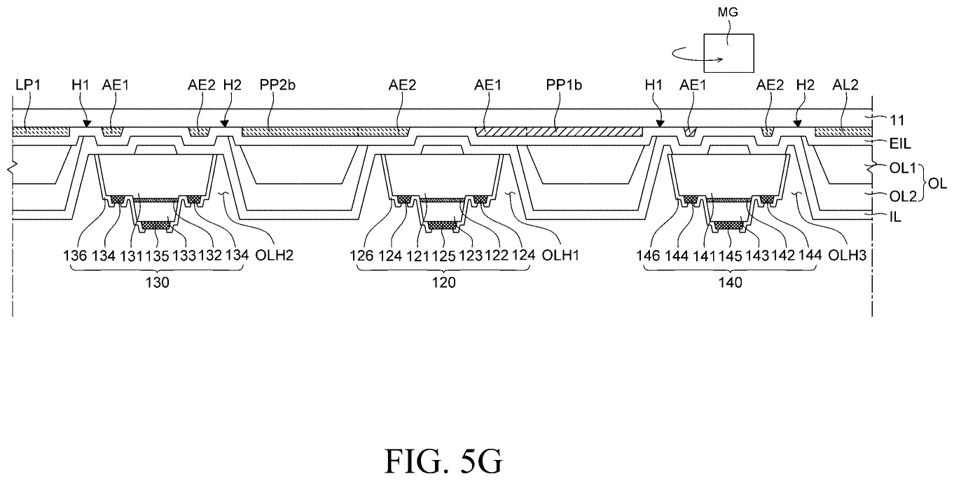

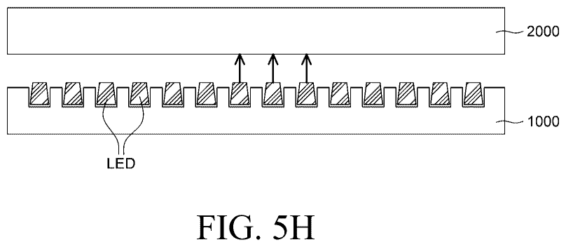

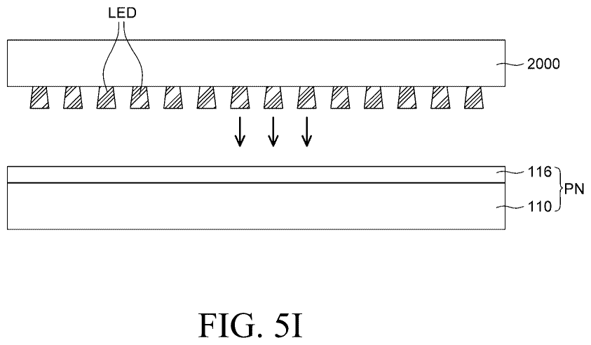

Hereinafter, a method of manufacturing a display device 100 according to the implementation of the present specification by using the assembling substrate 10 according to the implementation of the present specification will be described with reference to FIGS. 5A to 5I.

FIGS. 5A to 5I are process diagrams for explaining the method of manufacturing the display device according to the implementation of the present specification. FIGS. 5A and 5G are views for explaining a process of self-assembling a light-emitting element LED onto the assembling substrate 10. FIGS. 5B to 5D are views for explaining the plurality of light-emitting elements LED according to the implementation of the present specification. FIG. 5B is a view for explaining the first light-emitting element 120. FIG. 5C is a view for explaining the second light-emitting element 130. FIG. 5D is a view for explaining the third light-emitting element 140. FIG. 5H is a view for explaining a process of transferring the light-emitting elements LED on the assembling substrate 10 to the donor 20. FIG. 5I is a view for explaining a process of transferring the light-emitting elements LED on the donor 20 to a display panel PN.

With reference to FIG. 5A, the plurality of light-emitting elements LED are self-assembled on the assembling substrate 10.

First, the plurality of light-emitting elements LED grown on a wafer are inputted to a chamber CB filled with the fluid WT. The fluid WT may include water or the like, and the chamber CB filled with the fluid WT may have a shape opened at an upper side thereof.

The plurality of light-emitting elements LED may include the plurality of first light-emitting elements 120, the plurality of second light-emitting elements 130, and the plurality of third light-emitting elements 140 configured to emit light beams with different colors.

The plurality of light-emitting elements LED may be formed on different wafers in accordance with light-emitting wavelength bands. For example, in case that the first light-emitting element 120 emits light in a red wavelength band, the first light-emitting element 120 may be formed on a gallium arsenide (GaAs) wafer. In addition, in case that the second light-emitting element 130 and the third light-emitting element 140 emit light in a green or blue wavelength band, the second light-emitting element 130 and the third light-emitting element 140 may be formed on a sapphire wafer.

Therefore, the first light-emitting element 120 may include a semiconductor layer different in permittivity from the second light-emitting element 130 and the third light-emitting element 140. For example, the permittivity of the semiconductor layer of the second light-emitting element 130 and the permittivity of the semiconductor layer of the third light-emitting element 140 may be lower than the permittivity of the semiconductor layer of the first light-emitting element 120.

With reference to FIG. 5B together, the first light-emitting element 120 includes a first n-type semiconductor layer 121, a first light-emitting layer 122, a first p-type semiconductor layer 123, first n-type electrodes 124, a first p-type electrode 125, and a first encapsulation film 126.

The first p-type semiconductor layer 123 is disposed on the first n-type semiconductor layer 121. The first n-type semiconductor layer 121 and the first p-type semiconductor layer 123 may each be a layer formed by doping a particular material with n-type and p-type impurities. For example, the first n-type semiconductor layer 121 and the first p-type semiconductor layer 123 may each be a layer formed by doping a material, such as aluminum gallium indium phosphide (AIGaInP), indium aluminum phosphide (InAlP), or gallium arsenide (GaAs), with n-type and p-type impurities. Further, the p-type impurity may be magnesium, zinc (Zn), beryllium (Be), or the like. The n-type impurity may be silicon (Si), germanium, tin (Sn), or the like. However, the present specification is not limited thereto.

Meanwhile, the first light-emitting element 120 may further include an etch stop layer below the first semiconductor layer 121 to suppress damage to the first semiconductor layer 121. However, the present specification is not limited thereto.

The first light-emitting layer 122 is disposed between the first n-type semiconductor layer 121 and the first p-type semiconductor layer 123. The first light-emitting layer 122 may emit light by receiving positive holes and electrons from the first n-type semiconductor layer 121 and the first p-type semiconductor layer 123. The first light-emitting layer 122 may be configured as a single layer or a multi-quantum well (MQW) structure. For example, the first light-emitting layer 122 may be made of aluminum gallium indium phosphide (AIGaInP), indium gallium phosphide (GaInP), or the like. However, the present specification is not limited thereto.

The first n-type electrode 124 is disposed on the first n-type semiconductor layer 121. The first n-type electrode 124 may be disposed on a top surface of the first n-type semiconductor layer 121 exposed from the first light-emitting layer 122 and the first p-type semiconductor layer 123. The first n-type electrode 124 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present specification is not limited thereto.

The first p-type electrode 125 is disposed on the first p-type semiconductor layer 123. The first p-type electrode 125 may be disposed on a top surface of the first p-type semiconductor layer 123. The first p-type electrode 125 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present specification is not limited thereto.

Meanwhile, any one of the first n-type electrode 124 and the first p-type electrode 125 may include a ferromagnetic material. For example, the first p-type electrode 125 may include a ferromagnetic material such as nickel (Ni).

Next, the first encapsulation film 126 is disposed to surround the first n-type semiconductor layer 121, the first light-emitting layer 122, the first p-type semiconductor layer 123, the first n-type electrode 124, and the first p-type electrode 125. The first encapsulation film 126 may be made of an insulating material and protect the first n-type semiconductor layer 121, the first light-emitting layer 122, and the first p-type semiconductor layer 123. Further, contact holes, through which the first n-type electrodes 124 and the first p-type electrode 125 are exposed, may be formed in the first encapsulation film 126, such that the first n-type electrodes 124 and the first p-type electrode 125 may be electrically connected to a display panel.

With reference to FIG. 5C, the second light-emitting element 130 includes a second n-type semiconductor layer 131, a second light-emitting layer 132, a second p-type semiconductor layer 133, second n-type electrodes 134, a second p-type electrode 135, and a second encapsulation film 136.

The second p-type semiconductor layer 133 is disposed on the second n-type semiconductor layer 131. The second n-type semiconductor layer 131 and the second p-type semiconductor layer 133 may be made of a material with lower permittivity than that of the first n-type semiconductor layer 121 and the first p-type semiconductor layer 123. For example, the second n-type semiconductor layer 131 and the second p-type semiconductor layer 133 may each be a layer formed by doping a material, such as gallium nitride (GaN), with n-type and p-type impurities. However, the present specification is not limited thereto.

The second light-emitting layer 132 is disposed between the second n-type semiconductor layer 131 and the second p-type semiconductor layer 133. The second light-emitting layer 132 may be made of a material with lower permittivity than that of the first light-emitting layer 122. For example, the second light-emitting layer 132 may be made of aluminum indium gallium nitride (AlInGaN), indium gallium nitride (InGaN), gallium nitride (GaN), or the like. However, the present specification is not limited thereto.

One or more second n-type electrodes 134 are disposed on the second n-type semiconductor layer 131, and the second p-type electrode 135 is disposed on the second p-type semiconductor layer 133. Any one of the second n-type electrode 134 or the second p-type electrode 135 may include a ferromagnetic material. For example, the second p-type electrode 135 may include a ferromagnetic material such as nickel (Ni).

Next, the second encapsulation film 136 is disposed to surround the second n-type semiconductor layer 131, the second light-emitting layer 132, the second p-type semiconductor layer 133, the second n-type electrode 134, and the second p-type electrode 135.

With reference to FIG. 5D, the third light-emitting element 140 includes a third n-type semiconductor layer 141, a third light-emitting layer 142, a third p-type semiconductor layer 143, third n-type electrodes 144, a third p-type electrode 145, and a third encapsulation film 146.

The third p-type semiconductor layer 143 is disposed on the third n-type semiconductor layer 141. The third n-type semiconductor layer 141 and the third p-type semiconductor layer 143 may be made of a material with lower permittivity than that of the first n-type semiconductor layer 121 and the first p-type semiconductor layer 123. For example, the third n-type semiconductor layer 141 and the third p-type semiconductor layer 143 may each be a layer formed by doping a material, such as gallium nitride (GaN), with n-type and p-type impurities. However, the present specification is not limited thereto.

The third light-emitting layer 142 is disposed between the third n-type semiconductor layer 141 and the third p-type semiconductor layer 143. The third light-emitting layer 142 may be made of a material with lower permittivity than that of the first light-emitting layer 122. For example, the third light-emitting layer 142 may be made of aluminum indium gallium nitride (AlInGaN), indium gallium nitride (InGaN), gallium nitride (GaN), or the like. However, the present specification is not limited thereto.

The third n-type electrode 144 is disposed on the third n-type semiconductor layer 141, and the third p-type electrode 145 is disposed on the third p-type semiconductor layer 143. Any one of the third n-type electrode 144 and the third p-type electrode 145 may include a ferromagnetic material having relative magnetic permeability different from relative magnetic permeability of a ferromagnetic material included in the first n-type electrode 124 or the first p-type electrode 125 and relative magnetic permeability of a ferromagnetic material included in the second n-type electrode 134 or the second p-type electrode 135. For example, the relative magnetic permeability of the ferromagnetic material included in the third p-type electrode 145 may be lower than the relative magnetic permeability of the ferromagnetic material included in the first p-type electrode 125 and the relative magnetic permeability of the ferromagnetic material included in the second p-type electrode 135. For example, the third p-type electrode 145 may include cobalt (Co). However, the present specification is not limited thereto.

Next, the third encapsulation film 146 is disposed to surround the third n-type semiconductor layer 141, the third light-emitting layer 142, the third p-type semiconductor layer 143, the third n-type electrode 144, and the third p-type electrode 145.

Meanwhile, the first light-emitting element 120, the second light-emitting element 130, and the third light-emitting element 140 may have the same shape. For example, all the planar shapes of the first light-emitting element 120, the second light-emitting element 130, and the third light-emitting element 140 may be circular shapes or elliptical shapes.

According to the implementation of the present specification, even though the first light-emitting element 120, the second light-emitting element 130, and the third light-emitting element 140 have the same shape in the display device 100, the plurality of light-emitting elements LED may be self-assembled at positions corresponding to a plurality of subpixels SP while the light-emitting elements LED are self-assembled. However, the shapes of the plurality of light-emitting elements LED are example, and the present specification is not limited thereto.

However, the present specification is not limited thereto. The first light-emitting element 120, the second light-emitting element 130, and the third light-emitting element 140 may have different shapes. For example, the planar shape of the first light-emitting element 120 may be a circular shape, the planar shape of the second light-emitting element 130 may be an elliptical shape, and the planar shape of the third light-emitting element 140 may be an elliptical shape different from the planar shape of the second light-emitting element 130.

Next, the assembling substrate 10 may be positioned on the chamber CB filled with the light-emitting elements LED. The assembling substrate 10, which has the plurality of opening portions OLH, and the chamber CB may be disposed to face each other.

Next, a magnet MG may be positioned on the assembling substrate 10. The light-emitting elements LED, which are submerged or suspended on a bottom of the chamber CB, may be moved toward the assembling substrate 10 by a magnetic force of the magnet MG.

In this case, in case that the plurality of light-emitting elements LED have horizontal structures, an upper portion of the light-emitting element LED on which the n-type electrode and the p-type electrode of the light-emitting element LED are formed may have a stepped portion. Therefore, the n-type electrode and the p-type electrode, which include the ferromagnetic materials, may be disposed on the upper portions of the plurality of light-emitting elements LED having the stepped portions. Therefore, in case that a magnitude of a magnetic field formed on the plurality of light-emitting elements LED and the magnet MG is large, the upper portions of the plurality of light-emitting elements LED having the stepped portions may be guided to the plurality of opening portions OLH so as to be directed toward the assembling electrode AE. However, in this case, the plurality of light-emitting elements LED is less affected by the electric field generated by the assembling electrode AE, and the plurality of light-emitting elements LED may be withdrawn from the plurality of opening portions OLH while moving along the magnet MG during the process in which the magnet MG moves on the assembling substrate 10. Therefore, lower portions of the plurality of light-emitting elements LED, on which flat surfaces are disposed, may be guided to face the plurality of opening portions OLH. Therefore, the lower portions of the plurality of light-emitting elements LED, on which the flat surfaces are disposed, may be stably fixed to the plurality of opening portions OLH without being withdrawn from the plurality of opening portions OLH even though the magnet MG moves on the assembling substrate 10.

The light-emitting elements LED, which have been moved toward the assembling substrate 10 by the magnet MG, may be self-assembled on the assembling substrate 10 by the electric fields formed between the plurality of assembling electrodes AE.

Specifically, the plurality of light-emitting elements LED may be self-assembled in the opening portions OLH of the organic layer OL by applying voltages to the plurality of assembling lines AL and the plurality of assembling electrodes AE. For example, the electric fields may be formed by applying different alternating current voltages to the plurality of first assembling lines AL1, the plurality of first assembling electrodes AE1, the plurality of second assembling lines AL2, and the plurality of second assembling electrodes AE2. The light-emitting element LED may have a polarity by being dielectrically polarized by the electric field. Further, the dielectrically polarized light-emitting element LED may be fixed or moved in a particular direction by dielectrophoresis (DEP), i.e., the electric field. Therefore, the plurality of light-emitting elements LED may be temporarily self-assembled inside the opening portions OLH of the assembling substrate 10 by using the dielectrophoresis.

Meanwhile, in case that the plurality of light-emitting elements LED are different in permittivity, the plurality of light-emitting elements LED may be self-assembled at different voltages. For example, the plurality of first light-emitting elements 120 may be self-assembled at a first voltage, and the plurality of second light-emitting elements 130 and the plurality of third light-emitting elements 140 may be self-assembled at a second voltage. For example, in case that the permittivity of the plurality of second light-emitting elements 130 and the permittivity of the plurality of third light-emitting elements 140 are lower than the permittivity of the plurality of first light-emitting elements 120, the plurality of second light-emitting elements 130 and the plurality of third light-emitting elements 140 may be self-assembled at the second voltage higher than the first voltage. For example, the plurality of first light-emitting elements 120 may be self-assembled at the first voltage, and the plurality of second light-emitting elements 130 and the plurality of third light-emitting elements 140 may be self-assembled at the second voltage higher than the first voltage.

First, with reference to FIG. 5E, the plurality of first light-emitting elements 120 are assembled on the assembling substrate 10 by applying the first voltage to the plurality of assembling electrodes AE. In this case, because the plurality of second light-emitting elements 130 and the plurality of third light-emitting elements 140 have the permittivity lower than that of the plurality of first light-emitting elements 120, a dielectrophoresis force generated between the plurality of second light-emitting elements 130, the plurality of third light-emitting elements 140, and the plurality of assembling electrodes AE may be lower than a dielectrophoresis force generated between the plurality of first light-emitting elements 120 and the plurality of assembling electrodes AE. Therefore, only the plurality of first light-emitting elements 120 may be assembled on the plurality of assembling electrodes AE to which the first voltage is applied.

Meanwhile, an area in which the plurality of first opening portions OLH1 and the plurality of assembling electrodes AE overlap one another among the plurality of opening portions OLH of the assembling substrate 10 may be larger than an area in which the plurality of second opening portions OLH2 overlap the plurality of assembling electrodes AE and an area in which the plurality of third opening portions OLH3 overlap the plurality of assembling electrodes AE. Therefore, the electric field formed in the plurality of first opening portions OLH1 is larger than the electric field formed in the plurality of second opening portions OLH2 and the electric field formed in the plurality of third opening portions OLH3, such that the plurality of first light-emitting elements 120 may be self-assembled in the plurality of first opening portions OLH1 among the plurality of opening portions OLH.

Next, with reference to FIG. 5F, the plurality of second light-emitting elements 130 are assembled on the assembling substrate 10 by applying the second voltage to the plurality of assembling electrodes AE. In this case, because the relative magnetic permeability of the ferromagnetic material included in the plurality of second light-emitting elements 130 is higher than the relative magnetic permeability of the ferromagnetic material included in the plurality of third light-emitting elements 140, the magnetic field formed between the plurality of second light-emitting elements 130 and the magnet MG may be larger than the magnetic field formed between the plurality of third light-emitting elements 140 and the magnet MG. Therefore, a speed at which the plurality of second light-emitting elements 130 move toward the assembling substrate 10 may be higher than a speed at which the plurality of third light-emitting elements 140 move toward the assembling substrate 10. Therefore, the plurality of second light-emitting elements 130 may be assembled on the assembling substrate 10 before the plurality of third light-emitting elements 140 are assembled on the assembling substrate 10.

Meanwhile, an area in which the plurality of second opening portions OLH2 and the plurality of assembling electrodes AE overlap one another among the plurality of opening portions OLH of the assembling substrate 10 may be larger than an area in which the plurality of third opening portions OLH3 overlap the plurality of assembling electrodes AE. Therefore, the electric field formed in the plurality of second opening portions OLH2 may be larger than the electric field formed in the plurality of third opening portions OLH3. Therefore, the plurality of second light-emitting elements 130 may be self-assembled in the plurality of second opening portions OLH2 among the plurality of opening portions OLH.

Meanwhile, the ferromagnetic material may be disposed on the upper portions of the plurality of light-emitting elements LED. Therefore, the plurality of light-emitting elements LED may be guided to the plurality of opening portions OLH in a direction in which the upper portions of the plurality of light-emitting elements LED face the plurality of opening portions OLH. That is, a probability in which the plurality of light-emitting elements LED will be assembled in the plurality of opening portions OLH in a reverse direction may be increased as the magnitude of the magnetic field formed between the plurality of light-emitting elements LED and the magnet MG is excessively smaller than the electric field formed in the plurality of opening portions OLH. Therefore, the plurality of second light-emitting elements 130 may be assembled in the plurality of second opening portions OLH2 in a forward direction, whereas the plurality of second light-emitting elements 130 may be assembled in the reverse direction in the plurality of third opening portions OLH3 in which the electric field smaller than the electric field formed in the plurality of second opening portions OLH2 is formed.

The plurality of second light-emitting elements 130 assembled in the plurality of second opening portions OLH2 in the forward direction may be stably fixed to the assembling substrate 10, and the plurality of second light-emitting elements 130 assembled in the plurality of third opening portions OLH3 in the reverse direction may be withdrawn from the plurality of third opening portions OLH3 while moving in the direction in which the magnet MG moves. Therefore, the plurality of withdrawn second light-emitting elements 130 may be assembled in the plurality of second opening portions OLH2 in the forward direction.

Next, with reference to FIG. 5G, the plurality of third light-emitting elements 140 are assembled on the assembling substrate 10 by applying the second voltage to the plurality of assembling electrodes AE.

Because the relative magnetic permeability of the ferromagnetic material included in the plurality of third light-emitting elements 140 is lower than the relative magnetic permeability of the ferromagnetic material included in the plurality of second light-emitting elements 130, the magnetic field formed between the plurality of third light-emitting elements 140 and the magnet MG may be smaller than the magnetic field formed between the plurality of second light-emitting elements 130 and the magnet MG. Therefore, the plurality of third light-emitting elements 140 may be guided to the assembling substrate 10 relatively later than the plurality of second light-emitting elements 130. Therefore, the plurality of third light-emitting elements 140 may be assembled on the assembling substrate 10 after the plurality of second light-emitting elements 130 are assembled on the assembling substrate 10.

In this case, the plurality of third light-emitting elements 140 may be assembled in the plurality of third opening portions OLH3 in the state in which the plurality of first light-emitting elements 120 and the plurality of second light-emitting elements 130 are respectively assembled in the plurality of first opening portions OLH1 and the plurality of second opening portions OLH2 among the plurality of opening portions OLH of the assembling substrate 10. In this case, in accordance with the difference in size between the first hole H1 and the second hole H2 disposed in each of the plurality of second opening portions OLH2 and each of the plurality of third opening portions OLH3, an area of each of the plurality of assembling electrodes AE overlapping the plurality of third light-emitting elements 140 may be smaller than an area of each of the plurality of assembling electrodes AE overlapping the plurality of second light-emitting elements 130, and a magnitude of the dielectrophoresis force formed between the plurality of third light-emitting elements 140 and the plurality of assembling electrodes AE may be smaller than a magnitude of the dielectrophoresis force formed between the plurality of second light-emitting elements 130 and the plurality of assembling electrodes AE.

After the self-assembling is completed, the fluid WT may be evaporated from the assembling substrate 10. In this case, the light-emitting element LED may be fixed to the inside of the opening portion OLH by forming an electric field between the assembling electrodes AE until the fluid WT is completely evaporated. Further, the electric field may be removed after the assembling substrate 10 is completely dried. In this case, even after the electric field is removed, the light-emitting element LED may be temporarily fixed to the assembling substrate 10 by a van der Waals force.

Next, with reference to FIG. 5H, the plurality of light-emitting elements LED on the assembling substrate 10 are transferred to the donor 20.

First, the assembling substrate 10 and the donor 20 are aligned so that the plurality of light-emitting elements LED and the donor 20 face one another. After the assembling substrate 10 and the donor 20 are aligned, the assembling substrate 10 and the donor 20 may be joined, such that the upper portion of the light-emitting element LED may be in contact with the donor 20. In this case, the donor 20 is made of a material having an adhesive force, such that the upper portions of the plurality of light-emitting elements LED may be bonded to the donor 20 and moved to the donor 20 from the assembling substrate 10.

The donor 20 may be made of a polymer material having viscoelasticity, e.g., polydimethylsiloxane (PDMS), polyurethane acrylate (PUA), polyethylene glycol (PEG), polymethylmethacrylate (PMMA), polystyrene (PS), epoxy resin, urethane resin, acrylic resin, or the like. However, the present specification is not limited thereto.

Next, with reference to FIG. 5I, the plurality of light-emitting elements LED on the donor 20 are transferred onto a bonding layer 116 of the display panel PN.

First, the donor 20 and the display panel PN formed with the bonding layer 116 are aligned. The display panel PN and the donor 20 may be aligned after the donor 20 is disposed so that the plurality of light-emitting elements LED on the donor 20 and the bonding layer 116 of the display panel PN face one another.

The donor 20 and the display device 100 may be joined, such that the light-emitting element LED on the donor 20 may be transferred onto the bonding layer 116. The plurality of light-emitting elements LED disposed on the donor 20 are disposed in the arrangement corresponding to the plurality of subpixels SP, such that all the light-emitting elements LED on the donor 20 may be transferred to the display panel PN at once without selectively transferring the light-emitting element LED. The plurality of light-emitting elements LED transferred to the display panel PN may be temporarily fixed by being attached to the bonding layer 116.

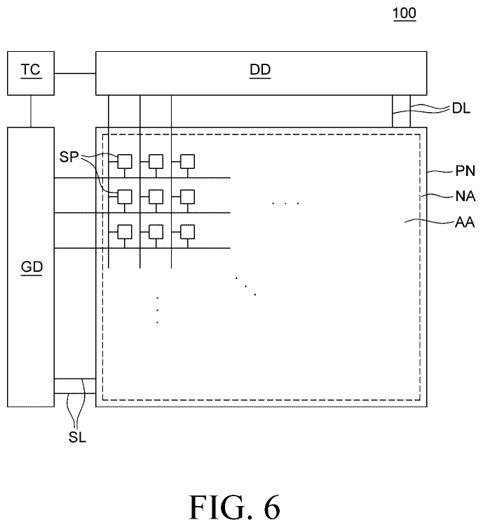

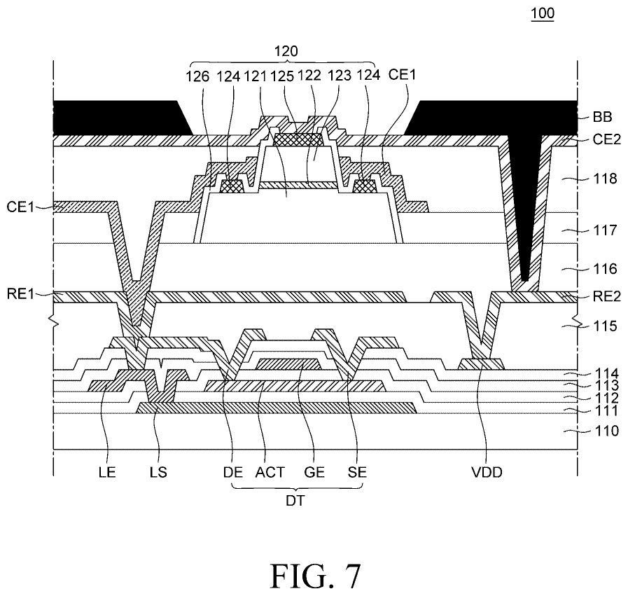

Hereinafter, the display device 100 according to the implementation of the present specification using the assembling substrate 10 and the donor 20 according to the implementation of the present specification will be described with reference to FIGS. 6 and 7.

FIG. 6 is a schematic configuration view of the display device according to the implementation of the present specification. For convenience of description, FIG. 6 illustrates only the display panel PN, a gate driver GD, a data driver DD, and a timing controller TC among various constituent elements of the display device 100.

With reference to FIG. 6, the display device 100 includes the display panel PN including the plurality of subpixels SP, the gate driver GD configured to supply various types of signals to the display panel PN, and the timing controller TC configured to control the data driver DD, the gate driver GD, and the data driver DD.

The drivers, such as the gate driver GD, the data driver DD, and the timing controller TC, may be connected to the display panel PN in various ways. For example, the gate driver GD may be mounted in a non-display area NA by a gate-in-panel (GIP) method or mounted between the plurality of subpixels SP by a gate-in-active area (GIA) method in a display area AA.

The display panel PN is configured to display images to a user and includes the plurality of subpixels SP. In the display panel PN, a plurality of scan lines SL and a plurality of data lines DL intersect one another, and each of the plurality of subpixels SP is connected to the scan line SL and the data line DL. In addition, although not illustrated in the drawings, the plurality of subpixels SP may be respectively connected to a high-potential power line, a low-potential power line, a reference line, and the like.

The display panel PN may have the display area AA, and the non-display area NA configured to surround the display area AA.

The display area AA is an area of the display device 100 in which images are displayed. The display area AA may include the plurality of subpixels SP constituting a plurality of pixels PX, and a circuit configured to operate the plurality of subpixels SP. The plurality of subpixels SP are minimum units that constitute the display area AA. The n subpixels SP may constitute one pixel PX. Alight-emitting element, a thin-film transistor for operating the light-emitting element, and the like may be disposed in each of the plurality of subpixels SP. The plurality of light-emitting elements may be differently defined depending on the type of the display panel PN. For example, in case that the display panel PN is an inorganic light-emitting display panel, the light-emitting element may be a light-emitting diode (LED) or a micro light-emitting diode (micro LED).

A plurality of signal lines for transmitting various types of signals to the plurality of subpixels SP are disposed in the display area AA. For example, the plurality of signal lines may include the plurality of data lines DL for supplying data voltages to the plurality of subpixels SP, and the plurality of scan lines SL for supplying gate voltages to the plurality of subpixels SP. The plurality of scan lines SL may extend in one direction in the display area AA and be connected to the plurality of subpixels SP. The plurality of data lines DL may extend in a direction different from one direction in the display area AA and be connected to the plurality of subpixels SP. In addition, a low-potential power line, a high-potential power line, and the like may be further disposed in the display area AA. However, the present specification is not limited thereto.

The non-display area NA is an area in which no image is displayed. The non-display area NA may include link lines and pad electrodes for transmitting signals to the subpixels SP in the display area AA. Alternatively, the non-display area NA may include drive ICs such as gate driver ICs and data driver ICs.

FIG. 7 is a cross-sectional view of the display device according to the implementation of the present specification.

The display panel PN includes the plurality of pixels PX each having the plurality of subpixels SP. The plurality of subpixels SP may each include the light-emitting element LED and a pixel circuit and independently emit light. The single pixel PX may include one or more first subpixels SP1, one or more second subpixels SP2, and one or more third subpixels SP3. For example, the single pixel PX may include two first subpixels SP1, two second subpixels SP2, and two third subpixels SP3. In this case, the first subpixel SP1 may be a red subpixel, the second subpixel SP2 may be a green subpixel, and the third subpixel SP3 may be a blue subpixel. However, the present specification is not limited thereto.

Next, with reference to FIG. 7 together, a substrate 110, a buffer layer 111, a gate insulation layer 112, a first interlayer insulation layer 113, a second interlayer insulation layer 114, a first planarization layer 115, the bonding layer 116, a second planarization layer 117, a third planarization layer 118, a bank BB, a driving transistor DT, the light-emitting element LED, a plurality of reflective electrodes RE, a plurality of connection electrodes CE, a light-blocking layer LS, and an auxiliary electrode LE are disposed in each of the plurality of subpixels SP of the display panel PN of the display device 100 according to the implementation of the present specification.

First, the substrate 110 is a component for supporting various constituent elements included in the display device 100 and may be made of an insulating material. For example, the substrate 110 may be made of glass, resin, or the like. In addition, the substrate 110 may include plastic such as polymer and may be made of a material having flexibility.

The light-blocking layer LS is disposed on each of the plurality of subpixels SP on the substrate 110. The light-blocking layer LS blocks light entering an active layer ACT of the driving transistor DT, which will be described below, from a lower side of the substrate 110. The light-blocking layer LS may block light entering the active layer ACT of the driving transistor DT, thereby minimizing a leakage current.

The buffer layer 111 is disposed on the substrate 110 and the light-blocking layer LS. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present specification is not limited thereto. However, the buffer layer 111 may be excluded in accordance with the type of substrate 110 or the type of transistor. However, the present specification is not limited thereto.

The driving transistor DT is disposed on the buffer layer 111. The driving transistor DT includes the active layer ACT, a gate electrode GE, a source electrode SE, and a drain electrode DE.

The active layer ACT is disposed on the buffer layer 111. The active layer ACT may be made of a semiconductor material such as an oxide semiconductor, amorphous silicon, or polysilicon. However, the present specification is not limited thereto.

The gate insulation layer 112 is disposed on the active layer ACT. The gate insulation layer 112 is an insulation layer for insulating the active layer ACT and the gate electrode GE. The gate insulation layer 112 may be configured as a single layer or multilayer made of silicon oxide (SiOx) or silicon nitride (SiNx). However, the present specification is not limited thereto.

The gate electrode GE is disposed on the gate insulation layer 112. The gate electrode GE may be made of an electrically conductive material, for example, copper (Cu), aluminum (Al), molybdenum (Mo), nickel (Ni), titanium (Ti), chromium (Cr), or an alloy thereof. However, the present specification is not limited thereto.

The first interlayer insulation layer 113 and the second interlayer insulation layer 114 are disposed on the gate electrode GE. Contact holes, through which the source electrode SE and the drain electrode DE are connected to the active layer ACT, are formed in the first interlayer insulation layer 113 and the second interlayer insulation layer 114. The first interlayer insulation layer 113 and the second interlayer insulation layer 114 may be insulation layers for protecting components disposed below the first interlayer insulation layer 113 and components disposed below the second interlayer insulation layer 114 and each configured as a single layer or multilayer made of silicon oxide (SiOx) or silicon nitride (SiNx). However, the present specification is not limited thereto.

The source electrode SE and the drain electrode DE are disposed on the second interlayer insulation layer 114 and electrically connected to the active layer ACT. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present specification is not limited thereto.

Meanwhile, in the present specification, the configuration has been described in which the first interlayer insulation layer 113 and the second interlayer insulation layer 114, i.e., the plurality of insulation layers are disposed between the gate electrode GE, the source electrode SE, and the drain electrode DE. However, only a single insulation layer may be disposed between the gate electrode GE, the source electrode SE, and the drain electrode DE. However, the present specification is not limited thereto.

Further, as illustrated in the drawings, in case that the plurality of insulation layers, such as the first interlayer insulation layer 113 and the second interlayer insulation layer 114, are disposed between the gate electrode GE, the source electrode SE, and the drain electrode DE, an electrode may be additionally formed between the first interlayer insulation layer 113 and the second interlayer insulation layer 114. The additionally formed electrode may define a capacitor together with other components disposed on a lower portion of the first interlayer insulation layer 113 or an upper portion of the second interlayer insulation layer 114.

The auxiliary electrode LE is disposed on the gate insulation layer 112. The auxiliary electrode LE is an electrode that electrically connects the light-blocking layer LS, which is disposed below the buffer layer 111, to any one of the source electrode SE and the drain electrode DE on the second interlayer insulation layer 114. For example, the light-blocking layer LS may be electrically connected to any one of the source electrode SE or the drain electrode DE through the auxiliary electrode LE so as not to be operated as a floating gate, thereby minimizing a change in threshold voltage of the driving transistor DT caused by the floating light-blocking layer LS. The drawing illustrates that the light-blocking layer LS is connected to the source electrode SE. However, the light-blocking layer LS may be connected to the drain electrode DE. However, the present specification is not limited thereto.

A power line VDD is disposed on the second interlayer insulation layer 114. The power line VDD may be electrically connected to the light-emitting element LED together with the driving transistor DT and allow the light-emitting element LED to emit light. The power line VDD may be made of an electrically conductive material, for example, copper (Cu), aluminum (Al), molybdenum (Mo), nickel (Ni), titanium (Ti), chromium (Cr), or an alloy thereof. However, the present specification is not limited thereto.

The first planarization layer 115 is disposed on the driving transistor DT and the power line VDD. The first planarization layer 115 may planarize an upper portion of the substrate 110 on which the driving transistor DT is disposed. The first planarization layer 115 may be configured as a single layer or multilayer and made of a photoresist or an acrylic-based organic material, for example. However, the present specification is not limited thereto.

The plurality of reflective electrodes RE, which are spaced apart from one another, are disposed on the first planarization layer 115. The plurality of reflective electrodes RE may serve to electrically connect the light-emitting element LED to the power line VDD and the driving transistor DT and serve as a reflective plate that reflects light, which is emitted from the light-emitting element LED, to the upper portion of the light-emitting element LED. The plurality of reflective electrodes RE may each be made of an electrically conductive material having excellent reflection performance and reflect the light, which is emitted from the light-emitting element LED, toward the upper portion of the light-emitting element LED.

The plurality of reflective electrodes RE include a first reflective electrode RE1 and a second reflective electrode RE2. The first reflective electrode RE1 may electrically connect the driving transistor DT and the light-emitting element LED. The first reflective electrode RE1 may be connected to the source electrode SE or the drain electrode DE of the driving transistor DT through a contact hole formed in the first planarization layer 115. Further, the first reflective electrode RE1 may be electrically connected to a first electrode and a first semiconductor layer of the light-emitting element LED through a first connection electrode CE1 to be described below.

The second reflective electrode RE2 may electrically connect the power line VDD and the light-emitting element LED. The second reflective electrode RE2 may be connected to the power line VDD through the contact hole, which is formed in the first planarization layer 115, and electrically connected to the p-type electrodes 125, 135, and 145 and the p-type semiconductor layers 123, 133, and 143 of the light-emitting elements LED through a second connection electrode CE2.

The bonding layer 116 is disposed on the plurality of reflective electrodes RE. Afront surface of the substrate 110 may be coated with the bonding layer 116, and the bonding layer 116 may fix the light-emitting element LED disposed on the bonding layer 116. For example, the bonding layer 116 may be made of any one material selected from adhesive polymer, epoxy resist, UV resin, a polyimide-based material, an acrylate-based material, a urethane-based material, and polydimethylsiloxane (PDMS). However, the present specification is not limited thereto.

The plurality of light-emitting elements LED are provided on the bonding layer 116 and disposed on each of the plurality of subpixels SP. The plurality of light-emitting elements LED may be elements configured to emit light by using an electric current and include the light-emitting elements LED configured to emit red light, green light, blue light, and the like. The plurality of light-emitting elements LED may implement light with various colors including white by using a combination of red light, green light, blue light, and the like. For example, the plurality of light-emitting elements LED may each be a light-emitting diode (LED) or a micro LED. However, the present specification is not limited thereto.

The plurality of light-emitting elements LED include the first light-emitting element 120, the second light-emitting element 130, and the third light-emitting element 140. The first light-emitting element 120 may be disposed on the first subpixel SP1, the second light-emitting element 130 may be disposed on the second subpixel SP2, and the third light-emitting element 140 may be disposed on the third subpixel SP3.

The first n-type semiconductor layer 121 of the first light-emitting element 120 is disposed on the bonding layer 116, and the first p-type semiconductor layer 123 is disposed on the first n-type semiconductor layer 121. The first n-type electrode 124 of the first light-emitting element 120 may be electrically connected to the driving transistor DT, and the first p-type electrode 125 of the first light-emitting element 120 may be electrically connected to the power line VDD.

In addition, the second n-type semiconductor layer 131 of the second light-emitting element 130 is disposed on the bonding layer 116, and the second p-type semiconductor layer 133 is disposed on the second n-type semiconductor layer 131. The second n-type electrode 134 of the second light-emitting element 130 may be electrically connected to the driving transistor DT, and the second p-type electrode 135 of the second light-emitting element 130 may be electrically connected to the power line VDD.

In addition, the third n-type semiconductor layer 141 of the third light-emitting element 140 is disposed on the bonding layer 116, and the third p-type semiconductor layer 143 is disposed on the third n-type semiconductor layer 141. The third n-type electrode 144 of the third light-emitting element 140 may be electrically connected to the driving transistor DT, and the third p-type electrode 145 of the third light-emitting element 140 may be electrically connected to the power line VDD.

The second planarization layer 117 and the third planarization layer 118 are disposed on the bonding layer 116. The second planarization layer 117 may partially overlap the side surfaces of the plurality of light-emitting elements LED and fix and protect the plurality of light-emitting elements LED. Specifically, FIG. 7 illustrates that the first encapsulation film 126 surrounds the entire side surface of the first n-type semiconductor layer 121. However, a part of the side surface of the first n-type semiconductor layer 121 may be exposed from the first encapsulation film 126. The light-emitting element LED manufactured on a wafer may be separated from the wafer and transferred to the display panel PN. However, a part of each of the encapsulation films 126, 136, and 146 may be torn during a process of separating the light-emitting element LED from the wafer. For example, a part of the first encapsulation film 126 adjacent to a lower edge of the first n-type semiconductor layer 121 of the first light-emitting element 120 may be torn during the process of separating the first light-emitting element 120 from the wafer, such that a part of a lower side surface of the first n-type semiconductor layer 121 may be exposed to the outside. The encapsulation films 136 and 146 of the second light-emitting element 130 and the third light-emitting element 140 may also be partially torn, such that the side surfaces of the n-type semiconductor layers 131 and 141 may be partially exposed. However, even though a lower portion of the first light-emitting element 120 is exposed from the first encapsulation film 126, the first connection electrode CE1 and the second connection electrode CE2 are formed after the second planarization layer 117, which covers the side surface of the first n-type semiconductor layer 121, is formed, thereby minimizing a short circuit defect.

In addition, the third planarization layer 118 may be formed to cover an upper portion of the second planarization layer 117 and an upper portion of the light-emitting element LED and have a contact hole through which the n-type electrodes 124, 134, and 144 and the p-type electrodes 125, 135, and 145 of the light-emitting element LED are exposed. The n-type electrodes 124, 134, and 144 and the p-type electrodes 125, 135, and 145 of the light-emitting element LED may be exposed from the third planarization layer 118. The third planarization layer 118 may be partially disposed in areas between the n-type electrodes 124, 134, and 144 and the p-type electrodes 125, 135, and 145, thereby minimizing a short-circuit defect.

The second planarization layer 117 and the third planarization layer 118 may each be configured as a single layer or multilayer and made of a photoresist or an acrylic-based organic material, for example. However, the present specification is not limited thereto. Meanwhile, in the present specification, the configuration has been described in which the second planarization layer 117 and the third planarization layer 118 are disposed. However, the planarization layer may be configured as a single layer. However, the present specification is not limited thereto.

The plurality of connection electrodes CE is disposed on the third planarization layer 118. The plurality of connection electrodes CE include the plurality of first connection electrodes CE1 and the second connection electrode CE2.

The first connection electrodes CE1 are electrodes that are respectively disposed on the plurality of subpixels SP and electrically connect the light-emitting elements LED and the driving transistors DT. The first connection electrode CE1 may be connected to the first reflective electrode RE1 through contact holes formed in the third planarization layer 118, the second planarization layer 117, and the bonding layer 116. Therefore, the first connection electrode CE1 may be electrically connected to any one of the source electrode SE and the drain electrode DE of the driving transistor DT through the first reflective electrode RE1. Further, the first connection electrodes CE1 may be connected to the n-type electrodes 124, 134, and 144 of the plurality of light-emitting elements LED through contact holes formed in the third planarization layer 118. Therefore, the first connection electrodes CE1 may electrically connect the driving transistors DT and the n-type electrodes 124, 134, and 144 and the n-type semiconductor layers 121, 131, and 141 of the plurality of light-emitting elements LED.

The second connection electrode CE2 is an electrode that electrically connects the light-emitting element LED and the power line VDD. The second connection electrode CE2 may be connected to the second reflective electrode RE2 through contact holes formed in the third planarization layer 118, the second planarization layer 117, and the bonding layer 116. Therefore, the second connection electrode CE2 may be electrically connected to the power line VDD through the second reflective electrode RE2. Further, the second connection electrodes CE2 may be connected to the p-type electrodes 125, 135, and 145 of the plurality of light-emitting elements LED through contact holes formed in the third planarization layer 118. Therefore, the second connection electrodes CE2 may electrically connect the power lines VDD and the p-type electrodes 125, 135, and 145 and the p-type semiconductor layers 123, 133, and 143 of the plurality of light-emitting elements LED.

Meanwhile, the first connection electrode CE1, which connects the driving transistor DT and the light-emitting element LED disposed on each of the plurality of subpixels SP, may be independently disposed on each of the plurality of subpixels SP. Further, the second connection electrodes CE2, which are disposed on each of the plurality of subpixels SP and connect the power lines VDD and the light-emitting elements LED, may be connected to each other. That is, because a power voltage of the power line VDD is applied in common to all the plurality of light-emitting elements LED of the plurality of subpixels SP, the single second connection electrode CE2 may be disposed on all the plurality of subpixels SP.

With reference to FIG. 7, portions corresponding to the p-type electrodes 125, 135, and 145 may be concavely formed so that the first connection electrodes CE1 of the plurality of subpixels SP may be connected only to the n-type electrodes 124, 134, and 144 of the light-emitting elements LED without being connected to the p-type electrodes 125, 135, and 145. The concave portions the first connection electrodes CE1 may overlap the p-type electrodes 125, 135, and 145 of the plurality of light-emitting elements LED. Further, the second connection electrode CE2 may extend convexly to the inside of the concave portion of the first connection electrode CE1 and be electrically connected to each of the p-type electrodes 125, 135, and 145 of the plurality of light-emitting elements LED. The convex portions of the second connection electrodes CE2 may overlap the p-type electrodes 125, 135, and 145 of the plurality of light-emitting elements LED.

The bank BB may be disposed on the third planarization layer 118. The bank BB may be disposed to be spaced apart from the plurality of light-emitting elements LED at predetermined intervals.

The bank BB may be made of an opaque material, for example, black resin to reduce a color mixture between the plurality of subpixels SP. However, the present specification is not limited thereto.

Meanwhile, the display device 100 according to the implementation of the present specification may be manufactured by self-assembling the plurality of light-emitting elements LED on the separate assembling substrate 10 and then transferring the plurality of self-assembled light-emitting elements LED from the assembling substrate 10 to the display panel PN by using the donor 20.

The plurality of light-emitting elements are assembled on the assembling substrate while corresponding to the subpixel pixels, and the plurality of light-emitting elements are transferred to the display panel in an intact manner in the arrangement in which the plurality of light-emitting elements are assembled on the assembling substrate. Therefore, in order to assemble the light-emitting elements, which emit light beams with different colors, at the positions respectively corresponding to the subpixels, one tray is filled only with the light-emitting elements configured to emit light beams with one identical color, and then the self-assembling is performed. However, in case that the self-assembling is performed in the state in which one tray is filled only with the light-emitting elements configured to emit light beams with one identical color, there is a problem in that the number of assembling processes is increased and the process time and process costs are increased because the light-emitting elements are assembled individually.

The display device 100 and the method of manufacturing the display device 100 according to the implementation of the present specification may control the assembling positions of the light-emitting elements LED on the basis of the difference in dielectrophoresis force in accordance with the dielectric properties of the plurality of light-emitting elements LED. The plurality of light-emitting elements LED are made of a semiconductor material. In this case, the light-emitting elements LED, which emit light beams with different colors, may be made of different semiconductor materials and different in permittivity. For example, in case that the first light-emitting element 120 emits light in a red wavelength band, the first light-emitting element 120 may be formed on a gallium arsenide (GaAs) wafer WA, and the first light-emitting layer 122 of the first light-emitting element 120 may include aluminum gallium indium phosphide (AIGaInP), indium gallium phosphide (GaInP), or the like. In contrast, in case that the second light-emitting element 130 and the third light-emitting element 140 emit light in a green or blue wavelength band, the second light-emitting element 130 and the third light-emitting element 140 may be formed on a sapphire wafer, and the second light-emitting layer 132 and the third light-emitting layer 142 of the second light-emitting element 130 and the third light-emitting element 140 may include aluminum indium gallium nitride (AlInGaN), indium gallium nitride (InGaN), gallium nitride (GaN), or the like. Therefore, the permittivity of the semiconductor layer of the second light-emitting element 130 and the permittivity of the semiconductor layer of the third light-emitting element 140 may be lower than the permittivity of the semiconductor layer of the first light-emitting element 120. Therefore, the first light-emitting element 120, together with the second light-emitting element 130 and the third light-emitting element 140, may be assembled on the assembling substrate 10 by using two or more different voltages. According to the display device 100 and the method of manufacturing the display device 100 according to the implementation of the present specification, the first light-emitting element 120, among the plurality of light-emitting elements LED, may be assembled on the assembling substrate 10 first on the basis of the difference in dielectrophoresis force in accordance with the dielectric properties even though the plurality of light-emitting elements LED, which emit light beams with different colors, are accommodated in one tray.

According to the display device 100 and the method of manufacturing the display device 100 according to the implementation of the present specification, the ferromagnetic materials, which are different in relative magnetic permeability, are disposed on the plurality of light-emitting elements LED, such that the light-emitting elements LED may be sequentially assembled. During the self-assembling process, the speed at which the plurality of light-emitting elements LED move toward the assembling substrate 10 may be controlled on the basis of the magnitude of the magnetic field formed between the plurality of light-emitting elements LED and the magnet MG. Therefore, the ferromagnetic materials, which are different in relative magnetic permeability, are disposed on the light-emitting elements LED that emit light beams with different colors, such that the light-emitting elements LED may be sequentially assembled. For example, nickel (Ni) may be included in the second light-emitting element 130, and cobalt (Co), which has lower relative magnetic permeability than nickel (Ni), may be included in the third light-emitting element 140. Therefore, the speed at which the third light-emitting element 140 moves toward the assembling substrate 10 may be relatively lower than the speed at which the second light-emitting element 130 moves toward the assembling substrate 10. Therefore, the third light-emitting element 140 may be assembled on the assembling substrate 10 after the second light-emitting element 130 is assembled on the assembling substrate 10. According to the display device 100 and the method of manufacturing the display device 100 according to the implementation of the present specification, the light-emitting elements LED may be sequentially assembled on the basis of the difference in dielectrophoresis force in accordance with the dielectric properties even though the plurality of light-emitting elements LED, which emit light beams with different colors, are accommodated in one tray.

That is, according to the display device 100 and the method of manufacturing the display device 100 according to the implementation of the present specification, the light-emitting elements LED may be sequentially assembled in accordance with the dielectric properties of the plurality of light-emitting elements LED and the relative magnetic permeability of the ferromagnetic material included in the light-emitting element LED. Therefore, according to the display device 100 and the method of manufacturing the display device 100 according to the implementation of the present specification, the plurality of light-emitting elements LED, which emit light beams with different colors, may be selectively assembled and simultaneously assembled even though the light-emitting elements LED having the same size are mixed in one tray. Therefore, in comparison with the case in which the self-assembling is performed in the state in which one tray is filled only with the light-emitting elements configured to emit light beams with one identical color, the number of assembling processes may be reduced, which may improve the production efficiency and reduce the manufacturing costs. Therefore, the manufacturing process may be simplified, and the process may be optimized.

The example implementations of the present disclosure can also be described as follows:

According to an aspect of the present disclosure, there is provided an assembling substrate which serves to assemble a plurality of light-emitting elements. The assembling substrate includes an assembly substrate, a plurality of first assembling electrodes disposed on the assembly substrate, a plurality of second assembling electrodes disposed on the assembly substrate and configured to face the plurality of first assembling electrodes at predetermined intervals, and an organic layer disposed on the assembly substrate and including a plurality of opening portions, wherein some of the plurality of first assembling electrodes include a plurality of first holes disposed to overlap the plurality of opening portions, wherein some of the plurality of second assembling electrodes include a plurality of second holes disposed to overlap the plurality of opening portions, and, wherein the plurality of first holes and the plurality of second holes are disposed to overlap the opening portions of some of the plurality of opening portions.

The plurality of opening portions may include a plurality of first opening portions, a plurality of second opening portions, and a plurality of third opening portions, and wherein the plurality of first holes and the plurality of second holes may be disposed to overlap the plurality of second opening portions and the plurality of third opening portions.

A size of each of the plurality of first holes and the plurality of second holes overlapping the plurality of third opening portions may be different from a size of each of the plurality of first holes and the plurality of second holes overlapping the plurality of second opening portions.

The size of each of the plurality of first holes and the plurality of second holes overlapping the plurality of third opening portions may larger than the size of each of the plurality of first holes and the plurality of second holes overlapping the plurality of second opening portions.

An interval between the plurality of first holes and the plurality of second holes in the plurality of third opening portions may smaller than an interval between the plurality of first holes and the plurality of second holes in the plurality of second opening portions.

The organic layer may cover a part of each of the plurality of first holes and a part of each of the plurality of second holes.

According to an aspect of the present disclosure, there is provided a method of manufacturing a display device. The method of manufacturing the display device includes self-assembling a plurality of light-emitting elements on an assembling substrate including a plurality of assembling electrodes, transferring the plurality of light-emitting elements self-assembled on the assembling substrate to a donor, and transferring the plurality of light-emitting elements on the donor to a display panel, wherein the plurality of light-emitting elements include a plurality of first light-emitting elements, a plurality of second light-emitting elements, and a plurality of third light-emitting elements, and wherein the self-assembling the plurality of light-emitting elements includes, assembling the plurality of first light-emitting elements on the assembling substrate by applying a first voltage to the plurality of assembling electrodes, and assembling the plurality of second light-emitting elements and the plurality of third light-emitting elements on the assembling substrate by applying a second voltage to the plurality of assembling electrodes.

The assembling the plurality of second light-emitting elements and the plurality of third light-emitting elements on the assembling substrate may include assembling the plurality of second light-emitting elements on the assembling substrate, and assembling the plurality of third light-emitting elements on the assembling substrate after the assembling the plurality of second light-emitting elements on the assembling substrate.

The plurality of light-emitting elements each may include a ferromagnetic material, and wherein relative magnetic permeability of the ferromagnetic material included in the plurality of third light-emitting elements may be different from relative magnetic permeability of the ferromagnetic material included in the plurality of second light-emitting elements.

The relative magnetic permeability of the ferromagnetic material included in the plurality of third light-emitting elements may lower than the relative magnetic permeability of the ferromagnetic material included in the plurality of second light-emitting elements.

The plurality of assembling electrodes may include portions having different areas, and wherein an area of the plurality of assembling electrodes overlapping the plurality of third light-emitting elements in the assembling the plurality of third light-emitting elements on the assembling substrate may smaller than an area of the plurality of assembling electrodes overlapping the plurality of second light-emitting elements in the assembling the plurality of second light-emitting elements on the assembling substrate.

The method of manufacturing a display device may further include moving the plurality of light-emitting elements toward the assembling substrate by a magnetic field formed between the plurality of light-emitting elements and a magnet along the magnet on the assembling substrate before the self-assembling the plurality of light-emitting elements, wherein in the assembling the plurality of second light-emitting elements and the plurality of third light-emitting elements on the assembling substrate, a magnitude of the magnetic field formed between the plurality of third light-emitting elements and the magnet may be smaller than a magnitude of the magnetic field formed between the plurality of second light-emitting elements and the magnet, and a magnitude of a dielectrophoresis force formed between the plurality of third light-emitting elements and the plurality of assembling electrodes may be smaller than a magnitude of a dielectrophoresis force formed between the plurality of second light-emitting elements and the plurality of assembling electrodes.

The second voltage may be higher than the first voltage.

Permittivity of the plurality of second light-emitting elements and permittivity of the plurality of third light-emitting elements may be lower than permittivity of the plurality of first light-emitting elements.

According to an aspect of the present disclosure, there is provided a device. The device includes a substrate on which a plurality of subpixels is defined, a plurality of transistors respectively disposed on the plurality of subpixels on the substrate, and a plurality of light-emitting elements disposed on the plurality of subpixels and including a plurality of semiconductor layers and a plurality of electrodes, wherein the plurality of light-emitting elements include a plurality of first light-emitting elements, a plurality of second light-emitting elements, and a plurality of third light-emitting elements, wherein the plurality of light-emitting elements each include the plurality of semiconductor layers and the plurality of electrodes, and wherein permittivity of the plurality of semiconductor layers of the plurality of second light-emitting elements and permittivity of the plurality of semiconductor layers of the plurality of third light-emitting elements are different from permittivity of the plurality of semiconductor layers of the plurality of first light-emitting elements.

The permittivity of the plurality of semiconductor layers of the plurality of second light-emitting elements and the permittivity of the plurality of semiconductor layers of the plurality of third light-emitting elements may be lower than the permittivity of the plurality of semiconductor layers of the plurality of first light-emitting elements.

The plurality of semiconductor layers of the plurality of first light-emitting elements may include aluminum gallium indium phosphide (AIGaInP), and wherein the plurality of semiconductor layers of the plurality of second light-emitting elements and the plurality of semiconductor layers of the plurality of third light-emitting elements may include indium gallium nitride (InGaN) or gallium nitride (GaN).

Relative magnetic permeability of the plurality of electrodes of the plurality of third light-emitting elements may be different from relative magnetic permeability of the plurality of electrodes of the plurality of second light-emitting elements.

The relative magnetic permeability of the plurality of electrodes of the plurality of third light-emitting elements may be lower than the relative magnetic permeability of the plurality of electrodes of the plurality of second light-emitting elements.

The plurality of second light-emitting elements includes nickel (Ni), and the plurality of third light-emitting elements may include cobalt (Co).

Although the example implementations of the present disclosure have been described in detail with reference to the accompanying drawings, the present disclosure is not limited thereto and may be embodied in many different forms without departing from the technical concept of the present disclosure. Therefore, the example implementations of the present disclosure are provided for illustrative purposes only but not intended to limit the technical concept of the present disclosure. The scope of the technical concept of the present disclosure is not limited thereto. Therefore, it should be understood that the above-described example implementations are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. An assembling substrate, which serves to assemble a plurality of light-emitting elements, the assembling substrate comprising:
an assembly substrate;
a plurality of first assembling electrodes disposed on the assembly substrate;
a plurality of second assembling electrodes disposed on the assembly substrate and configured to face the plurality of first assembling electrodes at predetermined intervals; and
an organic layer disposed on the assembly substrate and comprising a plurality of opening portions,
wherein some of the plurality of first assembling electrodes comprise a plurality of first holes disposed to overlap the plurality of opening portions,
wherein some of the plurality of second assembling electrodes comprise a plurality of second holes disposed to overlap the plurality of opening portions, and
wherein the plurality of first holes and the plurality of second holes are disposed to overlap the opening portions of some of the plurality of opening portions.

2. The assembling substrate of claim 1, wherein the plurality of opening portions comprise:
a plurality of first opening portions;
a plurality of second opening portions; and
a plurality of third opening portions, and
wherein the plurality of first holes and the plurality of second holes are disposed to overlap the plurality of second opening portions and the plurality of third opening portions.

3. The assembling substrate of claim 2, wherein a size of each of the plurality of first holes and the plurality of second holes overlapping the plurality of third opening portions is different from a size of each of the plurality of first holes and the plurality of second holes overlapping the plurality of second opening portions.

4. The assembling substrate of claim 3, wherein the size of each of the plurality of first holes and the plurality of second holes overlapping the plurality of third opening portions is larger than the size of each of the plurality of first holes and the plurality of second holes overlapping the plurality of second opening portions.

5. The assembling substrate of claim 4, wherein an interval between the plurality of first holes and the plurality of second holes in the plurality of third opening portions is smaller than an interval between the plurality of first holes and the plurality of second holes in the plurality of second opening portions.

6. The assembling substrate of claim 1, wherein the organic layer covers a part of each of the plurality of first holes and a part of each of the plurality of second holes.

7. A method of manufacturing a display device, the method comprising:
self-assembling a plurality of light-emitting elements on an assembling substrate comprising a plurality of assembling electrodes;
transferring the plurality of light-emitting elements self-assembled on the assembling substrate to a donor; and
transferring the plurality of light-emitting elements on the donor to a display panel,
wherein the plurality of light-emitting elements comprise a plurality of first light-emitting elements, a plurality of second light-emitting elements, and a plurality of third light-emitting elements, and
wherein the self-assembling the plurality of light-emitting elements comprises:
assembling the plurality of first light-emitting elements on the assembling substrate by applying a first voltage to the plurality of assembling electrodes; and
assembling the plurality of second light-emitting elements and the plurality of third light-emitting elements on the assembling substrate by applying a second voltage to the plurality of assembling electrodes.

8. The method of claim 7, wherein the assembling the plurality of second light-emitting elements and the plurality of third light-emitting elements on the assembling substrate comprises:
assembling the plurality of second light-emitting elements on the assembling substrate; and
assembling the plurality of third light-emitting elements on the assembling substrate after the assembling the plurality of second light-emitting elements on the assembling substrate.

9. The method of claim 8, wherein the plurality of light-emitting elements each includes a ferromagnetic material, and
wherein relative magnetic permeability of the ferromagnetic material included in the plurality of third light-emitting elements is different from relative magnetic permeability of the ferromagnetic material included in the plurality of second light-emitting elements.

10. The method of claim 9, wherein the relative magnetic permeability of the ferromagnetic material included in the plurality of third light-emitting elements is lower than the relative magnetic permeability of the ferromagnetic material included in the plurality of second light-emitting elements.

11. The method of claim 10, wherein the plurality of assembling electrodes comprises portions having different areas, and
wherein an area of the plurality of assembling electrodes overlapping the plurality of third light-emitting elements in the assembling the plurality of third light-emitting elements on the assembling substrate is smaller than an area of the plurality of assembling electrodes overlapping the plurality of second light-emitting elements in the assembling the plurality of second light-emitting elements on the assembling substrate.

12. The method of claim 7, further comprising:
moving the plurality of light-emitting elements toward the assembling substrate by a magnetic field formed between the plurality of light-emitting elements and a magnet along the magnet on the assembling substrate before the self-assembling the plurality of light-emitting elements,
wherein in the assembling the plurality of second light-emitting elements and the plurality of third light-emitting elements on the assembling substrate, a magnitude of the magnetic field formed between the plurality of third light-emitting elements and the magnet is smaller than a magnitude of the magnetic field formed between the plurality of second light-emitting elements and the magnet, and a magnitude of a dielectrophoresis force formed between the plurality of third light-emitting elements and the plurality of assembling electrodes is smaller than a magnitude of a dielectrophoresis force formed between the plurality of second light-emitting elements and the plurality of assembling electrodes.

13. The method of claim 7, wherein the second voltage is higher than the first voltage.

14. The method of claim 13, wherein permittivity of the plurality of second light-emitting elements and permittivity of the plurality of third light-emitting elements are lower than permittivity of the plurality of first light-emitting elements.

15. A display device comprising:
a substrate on which a plurality of subpixels is defined;
a plurality of transistors respectively disposed on the plurality of subpixels on the substrate; and
a plurality of light-emitting elements disposed on the plurality of subpixels and comprising a plurality of semiconductor layers and a plurality of electrodes,
wherein the plurality of light-emitting elements comprise:
a plurality of first light-emitting elements;
a plurality of second light-emitting elements; and
a plurality of third light-emitting elements,
wherein the plurality of light-emitting elements each comprise:
the plurality of semiconductor layers; and
the plurality of electrodes, and
wherein permittivity of the plurality of semiconductor layers of the plurality of second light-emitting elements and permittivity of the plurality of semiconductor layers of the plurality of third light-emitting elements are different from permittivity of the plurality of semiconductor layers of the plurality of first light-emitting elements.

16. The display device of claim 15, wherein the permittivity of the plurality of semiconductor layers of the plurality of second light-emitting elements and the permittivity of the plurality of semiconductor layers of the plurality of third light-emitting elements are lower than the permittivity of the plurality of semiconductor layers of the plurality of first light-emitting elements.

17. The display device of claim 16, wherein the plurality of semiconductor layers of the plurality of first light-emitting elements includes aluminum gallium indium phosphide (AIGaInP), and
wherein the plurality of semiconductor layers of the plurality of second light-emitting elements and the plurality of semiconductor layers of the plurality of third light-emitting elements include indium gallium nitride (InGaN) or gallium nitride (GaN).

18. The display device of claim 16, wherein relative magnetic permeability of the plurality of electrodes of the plurality of third light-emitting elements is different from relative magnetic permeability of the plurality of electrodes of the plurality of second light-emitting elements.

19. The display device of claim 18, wherein the relative magnetic permeability of the plurality of electrodes of the plurality of third light-emitting elements is lower than the relative magnetic permeability of the plurality of electrodes of the plurality of second light-emitting elements.

20. The display device of claim 18, wherein the plurality of second light-emitting elements includes nickel (Ni), and the plurality of third light-emitting elements include cobalt (Co).
